(19) United States
(12) Patent Application Publication
(10) Pub. No.: US 2023/0368763 A1
(43) Pub. Date: Nov. 16, 2023

(54) Anti-Vibration Fan Mounting Gasket

(71) Applicant: Martin Gossner, East Palo Alto, CA (US)

(72) Inventor: Martin Gossner, East Palo Alto, CA (US)

(21) Appl. No.: 17/744,306

(22) Filed: May 13, 2022

(51) Int. Cl. G10K 11/162; H05K 7/20

(52) U.S. Cl. CPC G10K 11/162; H05K 7/20172; G06F 1/20

(57) ABSTRACT

A device made of an elastomeric material that dampens vibrations caused by cooling fans. The device attaches to both faces of a cooling fan and fully decouples the fan from the enclosure. This reduces or eliminates auditory vibrations transmitted through the thermoplastic fan frame and fan mounting screws. The device achieves this decoupling through three different methods. Firstly, a large flat elastomer surface is placed between the cooling fan face and the electronic enclosure. Secondly, elastomeric protrusions prevent fan mounting screws from touching the cooling fan frame. Thirdly, a thin elastomeric wall extends around the outside of the cooling fan frame and prevents contact between adjacent cooling fans. Together, these features prevent auditory vibration transmission into the electronic enclosure. The flat elastomeric surface also creates an airtight seal between the cooling fan and enclosure. This seal prevents the formation of small air gaps which can result in an audible airflow leakage. The device can be configured for several different common cooling fan sizes and mounting hole patterns. Several of the device configurations are intended for fan arrays used by standard-sized computer cases and liquid-cooling radiators. In all configurations, the device functions to prevent vibration transmission from the cooling fan to the electronic enclosure.

### STATEMENT REGARDING FEDERALLY SPONSORED RESEARCH OR DEVELOPMENT

Not applicable

### REFERENCE TO SEQUENCE LISTING, A TABLE, OR A COMPUTER PROGRAM LISTING COMPACT DISC APPENDIX

Not applicable

### BACKGROUND OF THE INVENTION

Modern high-end electronics, in particular computer components, generate significant heat, which generally cannot be transferred away from the device through entirely passive methods. Thus, cooling fans are typically used in combination with heat sinks as an active airflow source. These fans intake cool air and exhaust warm air heated by the electronic components. The most common method for mounting a cooling fan is screwing the fan to the electronic enclosure. This mounting method creates the possibility for vibration transfer from the cooling fan's hub motor into the electronic enclosure. These transferred vibrations can fall within the audible frequency and result in an unpleasant noise heard by the device' user.

In the current competitive market, consumers desire both good airflow and low noise. Audible vibrations from a device can negatively impact the end user experience and discourage the consumer from buying a similar device in the future.

Several methods exist that attempt to mitigate or eliminate this vibration. Some cooling fans come with elastomeric pads that sit between the fan body and electronic enclosure. However, the metal mounting screw still contacts the fan body and electronic enclosure, creating a path for vibration transfer. Another method is to use an elastomeric gasket between the fan and chassis with elastomeric protrusions that enclose the screw thread. Similar to the first example, this method still allows for vibration transfer from the fan to the electronic enclosure via the mounting screw. Thus, there is a need for a device that can fully decouple a cooling fan from a electronic enclosure, with an elastomeric layer between any potentially contacting metal or plastic.

### BRIEF SUMMARY OF THE INVENTION

The problem identified above is addressed by a 2-part elastomeric device that fully decouples a cooling fan from the computer's electronic enclosure. Each part of the device has three key features: a flat surface with an orifice for the cooling fan, protrusions that prevent mounting screw contact with any point on the thermoplastic fan frame, a thin vertical border protrusion to prevent contact between adjacent cooling fans. The device also forms an airtight seal between the cooling fan and enclosure, preventing potential airflow leakage and its related noise effects. The elastomeric material used for the device, silicone, has high damping characteristics that act to isolate the vibrations caused by the cooling fan's hub motor. The 2-part device is placed on either side of the cooling fan, which separates the fan from any sheet metal or other undamped body. The device attaches to the fan with long mounting screws that extend the thickness of the fan's frame, and nylon or alloy threaded nuts. The device can be configured for multiple standardized fan arrays that are used by electronic enclosures or liquid-cooling radiators. Typically, these arrays are sized in some multiple of 80 mm, 92 mm, 120 mm or 140 mm cooling fans. When used in conjunction with a radiator, the device both dampens vibration transfer from the cooling fan to the electronic enclosure, but also from the cooling fan to the liquid-cooling radiator.

### BRIEF DESCRIPTION OF THE SEVERAL VIEWS OF THE DRAWING

FIG. 1 Shows a typical computer cooling fan

FIG. 2 Shows one of the two identical parts of the proposed device

FIG. 3 Shows a configuration of the device intended for an array of two cooling fans

FIG. 4 Shows the assembly of the proposed device and a typical computer cooling fan

FIG. 5 Shows a typical installation of a the proposed device and cooling fan onto an electronics enclosure

FIG. 6 Shows an exploded assembly view of the configuration described in FIG. 5

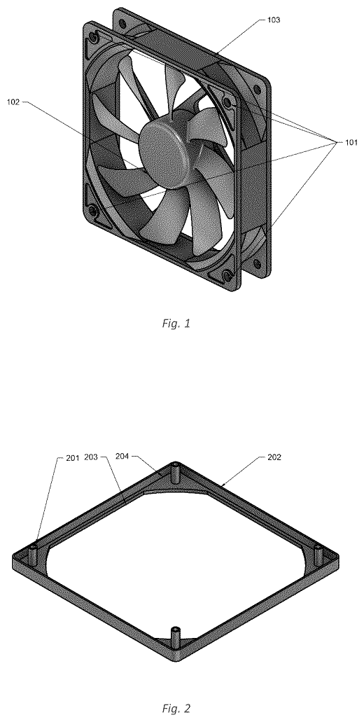

### DETAILED DESCRIPTION OF THE INVENTION

The following provides a detailed description of the proposed device and its application in consumer and enterprise areas. The detail provided aims to clearly and fully communicate the device's intent and function while not inhibiting future developments of this device from supporting new configurations.

The proposed device is intended for installation into consumer and enterprise focused electronic enclosures with standardized mounting patterns for cooling fans. Cooling fans are typically integrated into systems to facilitate the intake of colder air and exhaust of warmer air when passive cooling configurations are not sufficient. Cooling fans rely on a centrally mounted hub motor in order to rotate the fan blades; this motor creates vibrations that can transfer into an electronic enclosure (504) and, at certain frequencies, become audible to the end user. These audible vibrations are often unpleasant to listen to and negatively affect the user experience.

Typical cooling fans use four holes (101) to mount to an electronic enclosure. These holes are arranged in a standardized pattern in order to support as many individual enclosures as possible. The frame and blades of the fan (103, 102) are typically made of a hard thermoplastic such as ABS. In a typical installation, the thermoplastic fan frame (103) is placed in direct contact with the electronic enclosure. During operation, the thermoplastic fan frame directly transfers vibrations from the fan motor into the fan chassis (504). Electronic enclosures are usually made using thin gage SPCC or similar steel, which amplify vibrations from the fan. This auditory effect is particularly pronounced when the electronic enclosure has loose fitting parts that can rattle.

Some cooling fans have elastomeric pads that sit between the fan's thermoplastic frame (103) and the electronic enclosure (504). However, vibrations are still able to transfer through the mounting screws attaching to the fan's mounting points (101).

FIG. 2. illustrates one of the two identical halves of the proposed device. The device is made out of a solid elastomeric material with high damping properties such as silicone. The flat surface (204) directly contacts the fan's thermoplastic frame (103) and prevents vibrational transfer to the electronic enclosure. The large orifice (203) avoids restricting the airflow from the cooling fan the device affixes to. Together, the flat surface and orifice (204, 203) prevent a majority of the potential vibrational transfer from the fan to the electronic enclosure. The flat surface and orifice (204, 203) also create an airtight seal between the enclosure and cooling fan frame (103). This seal prevents air acceleration in a gap between the fan frame (103) and enclosure (504) which can produce an audible whistling noise. Elastomeric protrusions (201) fully enclose mounting screws and prevent the metal screw body from contacting the thermoplastic fan frame at the standardized mounting holes (101). A thin elastomeric wall (202) runs along the border of the device and contacts the side of the fan's thermoplastic frame (103). This elastomeric wall is beneficial when cooling fans are placed adjacent to one another; the wall prevents the fans' thermoplastic frames from contacting one another and amplifying vibrations.

The proposed device in FIG. 2 is to be made using a molding process for solid elastomers. The mold parting line is located in an area that will not inhibit the function of the proposed device.

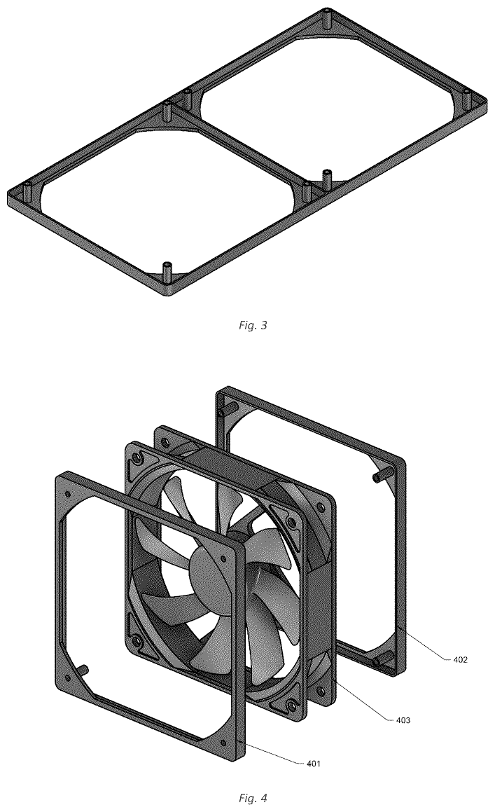

FIG. 3 shows an example of the proposed device configured for a twin cooling fan array. This twin array is most commonly used for higher airflow when adjacent fan mounting provisions are present, or for twin fan liquid-cooling radiators. In different configurations, the proposed device can provide all of the forthcoming acoustic dampening characteristics for other common fan array sizes, including but not limited to triple fan and quad fan arrays. When mounting a liquid cooler with the proposed device, a solid elastomeric layer (204) would be situated in between the sheet metal radiator body and the cooling fan's thermoplastic frame. This layer would prevent vibrational transfer from the cooling fan to the radiator body. The elastomeric surface on the other side of the cooling fan would contact the electronic enclosure (504) and provide the same vibrational damping as described above.

FIG. 4 describes the assembly order of the proposed device and a cooling fan. The two identical halves of the proposed device (401, 403) attach to each side of the cooling fan (402). The solid elastomeric surfaces (204) directly contact the thermoplastic frame (103). The elastomeric protrusions (201) extend through the mounting holes on the cooling fan frame (101). These protrusions may have a large enough interference fit to suitably attach the proposed device to the cooling fan. However, mounting screws (503) and accompanying nuts (502) are the most common method to affix the device to the cooling fan frame.

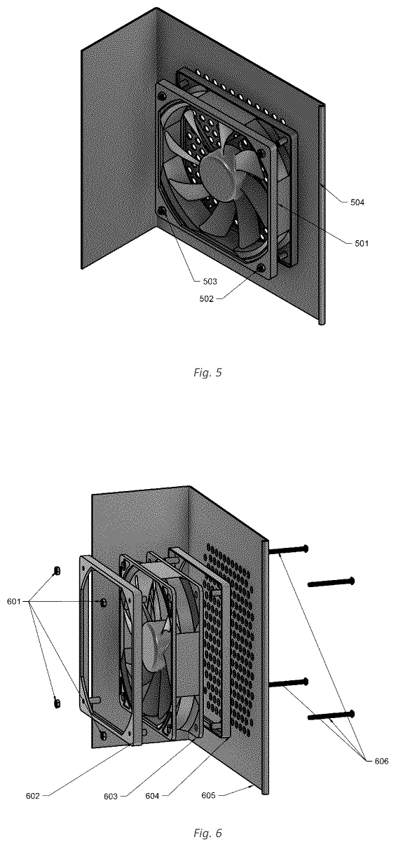

FIG. 5 provides an example of a cooling fan assembly with the proposed device mounted to an electronic enclosure panel. The cooling fan assembly (501) mounts to the electronic enclosure (504) and is attached using mounting screws (503) that extend through the fan assembly (501) and protrude far enough to be suitably tightened with mounting nuts (502). For applications where the cooling fan assembly is installed with a liquid cooling radiator on one side and a electronic enclosure on the other, the mounting screws (502) extend through the cooling fan assembly (501) and fasten into tapped threads on the radiator shroud body. For this application, no mounting nuts are necessary.

FIG. 6 is an exploded assembly diagram of FIG. 5's configuration. Each mounting screw (606) sits flush against the enclosure (605) on the opposite side of the cooling fan assembly (comprised of 602, 603, and 604). The mounting nuts (601) and mounting screws (606) are hand-tightened to avoid pinching the proposed device's elastomeric surfaces which could negatively affect its function.

1. A device that dampens vibrations caused by cooling fans comprising:
a. A two-part design that affixes to either side of the cooling fan and provides a layer between the thermoplastic fan frame and any undamped body.
b. A design that fully decouples the cooling fan from any surface that the fan is mounted to.

2. The device in claim 1, which has the following features:
a. A flat surface that is coplanar with the large side of the cooling fan and has an orifice for airflow. The dimensions for the orifice are described in the detail drawings.
b. Protrusions which prevent the metal mounting screw from contacting any part of the thermoplastic fan frame. The dimensions for these protrusions are defined in the detail drawings.
c. A thin vertical wall around the border of the device that contacts the cooling fan frame and prevents contact between adjacent cooling fans.

3. The device of claim 2, which uses a solid elastomeric material with a high damping coefficient, such as silicone, in order to achieve the intended vibration isolating characteristics.

4. The device of claim 2, which is mounted to a standardized hole pattern in a electronic enclosure and decouples the fan from the chassis surface.

5. The assembly of claim 4, which can be placed in between a liquid cooling radiator and the electronic enclosure, to decouple fan hub motor vibrations from being transferred to either of the two aforementioned components.

6. The assembly of claim 4, being able to be reconfigured for multiple fan arrays utilized by consumer and enterprise liquid cooling radiators, derived from either 120 mm or 140 mm cooling fan dimension standards.

7. The assembly of claim 4, being able to support cooling fans of different nominal thicknesses through the use of different length mounting screws.

8. The device of claim 3 which is produced through a molding process that enables the fabrication of solid elastomeric parts.
